(19) United States
(12) Patent Application Publication
(10) Pub. No.: US 2015/0214374 A1
(43) Pub. Date: Jul. 30, 2015

(54) CIRCUIT BOARD AND DISPLAY DEVICE

(71) Applicant: Sharp Kabushiki Kaisha, Osaka-shi, Osaka (JP)

(72) Inventors: Takeshi Hara, Osaka (JP); Hirohiko Nishiki, Osaka (JP); Izumi Ishida, Osaka (JP); Tohru Okabe, Osaka (JP); Manabu Daio, Osaka (JP)

(73) Assignee: Sharp Kabushiki Kaisha, Osaka-shi, Osaka (JP)

(21) Appl. No.: 14/424,357

(22) PCT Filed: Aug. 26, 2013
(86) PCT No.: PCT/JP2013/072763

§ 371 Date: Feb. 26, 2015

(30) Foreign Application Priority Data
Aug. 30, 2012 (JP) 2012-190646

(51) Int. Cl. H01L 29/786; H01L 27/12; H01L 29/45; H01L 29/24

(52) U.S. Cl. CPC H01L 29/7869; H01L 29/24; H01L 27/1225; H01L 27/1248; H01L 29/45

(57) ABSTRACT

The present invention provides a circuit substrate and a display device in which oxide semiconductor layers that TFTs include are produced according to areas where the oxide semiconductor layers are present, whereby the reliability thereof is sufficiently enhanced. This circuit substrate is a circuit substrate obtained by arranging semiconductor elements on a transparent substrate, each of the semiconductor elements including an oxide semiconductor layer. The circuit substrate includes a protective film arranged above the semiconductor element, and an organic insulating film arranged above the protective film. The organic insulating films have openings above at least a part of oxide semiconductor layers.

### TECHNICAL FIELDS

The present invention relates to a circuit substrate and a display device. More specifically, the present invention relates to a circuit substrate that can be suitably used for a display device that has a driver circuit near a display area and that has an oxide semiconductor layer, and a display device.

### BACKGROUND ART

A circuit substrate has an electronic circuit as a constituting element, and a circuit substrate that includes elements such as thin film transistors (TFTs), for example, is widely used for a constituting member of an electronic device such as a liquid crystal display device, an organic electroluminescence display device, an inorganic electroluminescence display device, and a display device that uses electrophoresis.

Below, a circuit configuration of a TFT array substrate included in a TFT-driven liquid crystal display panel will be explained as an example. A TFT array substrate generally has a pixel circuit that includes a structure in which TFTs, which are switching elements, are disposed for respective intersections of m×n matrix that is constituted of m rows of scanning lines and n columns of signal lines. The drain electrode of each TFT is electrically connected to a pixel electrode. Peripheral circuits such as a scan driver IC (integrated circuit) and data driver IC are electrically connected to gate wiring lines and source wiring lines respectively extending from the TFTs.

The circuits are affected by the characteristics of TFTs that are formed on the TFT substrate. That is, because the characteristics of TFTs formed on the TFT substrate vary depending on the material of the TFTs, factors such as whether a circuit can be operated by TFTs that are formed on the circuit substrate or not, whether the size of circuit is made large or not, and whether a reduction in yield is caused or not affect circuits that are formed on the TFT substrate. In conventional circuit substrates, a-Si (amorphous silicon) was widely used because a-Si allows TFTs to be formed at lower cost with greater ease.

In recent years, however, configurations in which an oxide semiconductor is used as another type of semiconductor compound for the channel layer of a TFT are disclosed (see Patent Documents 1 to 4, for example).

For example, a transparent thin film electric field transistor that uses a thin film made of a homologous compound InMO₃(ZnO)ₘ (M=In, Fe, Ga, or Al, m=an integer 1 or greater and less than 50) as an active layer is disclosed (see Patent Document 1, for example). Also disclosed is an active matrix type image display device in which an optical control element and an electric-field transistor for driving the optical control element are provided, an active layer of the electric-field transistor is made of an amorphous oxide having an electron carrier concentration of less than 10¹⁸/cm³, and the amorphous oxide includes at least one of Zn, In, and Sn (see Patent Document 2, for example). Also disclosed is an oxide semiconductor channel thin film transistor in which a channel layer is made of an oxide semiconductor having In-M-Zn—O (M is at least one of Ga, Al, and Fe) as a primary constituting element, the oxide semiconductor channel layer is covered by a protective film, and the protective film is made of silicon nitride, silicon oxide, or an organic substance (see Patent Document 3, for example).

Also disclosed is a thin film transistor that includes: a gate electrode; a gate insulating film formed on the gate electrode; an oxide semiconductor thin film layer that forms a channel region so as to correspond in position to the gate electrode; a channel protective layer including a first channel protective layer at a lower level and a second channel protective layer at an upper level; and source and drain electrodes that are formed on the channel protective layer and that are electrically connected to the oxide semiconductor thin film layer, the thin film transistor being configured such that the first channel protective layer is made of an oxide insulator and at least one of the first and second channel protective layers is made of a low-oxygen transmissive material (see Patent Document 4, for example).

### RELATED ART DOCUMENTS

### Patent Documents

Patent Document 1: Japanese Patent Application Laid-Open Publication No. 2004-103957

Patent Document 2: Japanese Patent Application Laid-Open Publication No. 2006-165528

Patent Document 3: Japanese Patent Application Laid-Open Publication No. 2007-73705

Patent Document 4: Japanese Patent Application Laid-Open Publication No. 2010-135462

### SUMMARY OF THE INVENTION

### Problems to be Solved by the Invention

Due to the high electron mobility of an oxide semiconductor, a semiconductor element having an oxide semiconductor layer can be made smaller or the like. However, in a circuit substrate including such a semiconductor element, how the reliability degrades (characteristics shift) varies depending on the driving voltage and the S/N ratio of electric current. In a circuit substrate for a display device, if a GDM (gate driver monolithic) is formed in a panel, for example, a panel display area and GDM area have different driving voltages and S/N ratios of electric current, and therefore, it is difficult to ensure the reliability in both areas.

Generally, when the circuit substrate is driven, a driver circuit area such as the GDM area has a higher voltage, larger current, and larger S/N ratio than those of pixel electrodes (display area), and therefore, how the reliability degrades (characteristic shift) varies between the display area and the peripheral circuit area.

In a circuit substrate for a mobile display device, it was, in some cases, inappropriate and not desirable to drive the peripheral circuits with a negative bias voltage from perspectives of reducing power consumption and the like.

The inventors of the present invention discovered that a conventional circuit substrate that includes a semiconductor element having an oxide semiconductor layer had room for improvement in appropriately handling a difference in how the reliability of each region degrades between oxide semiconductors of the display area and oxide semiconductors of the peripheral circuit area such as the GDM area, for example.

The inventions described Patent Documents above do not have a structure that allows an oxide semiconductor of a TFT to be optimized for each area or the like (forming respective parts of the oxide semiconductor separately to be appropriate for respective areas, for example). Thus, in this sense, the above-mentioned inventions had room for improvement in order to achieve excellent reliability of the circuit substrate.

The present invention was made in view of the current situation described above, and an object thereof is to provide a circuit substrate and a display device that can optimize the oxide semiconductor of a TFT depending on how the reliability deteriorates, thereby ensuring a sufficient level of reliability.

### Means for Solving Problems

The inventors of the present invention conducted various studies on a configuration that can improve reliability of a circuit substrate that is provided with a semiconductor element having an oxide semiconductor layer, and focused on a method to form an oxide semiconductor layer such that the oxide semiconductor layer is optimized for each area based on how the reliability of the circuit substrate degrades in the area. The inventors of the present invention have devised a configuration in which the circuit substrate includes a protective film that is placed at a layer above the semiconductor element and an organic insulating film that is placed at a layer above the productive film, and the organic insulating film has an opening formed on at least a part of the oxide semiconductor layer. The inventors of the present invention believed this configuration effectively solved the above-mentioned problems and reached the present invention.

That is, one aspect of the present invention may be a circuit substrate, including: a transparent substrate; semiconductor elements disposed on the transparent substrate, each of the semiconductor elements including an oxide semiconductor layer; a protective film over the semiconductor elements; and an organic insulating film over the protective film, wherein the organic insulating film has an opening in a position corresponding to at least a part of the oxide semiconductor layer.

The present invention will be described in detail below.

It is preferable that the opening be formed over a semiconductor element in an outer area of the circuit substrate but not over a semiconductor element in an inner area of the circuit substrate, or the opening be formed over a semiconductor element in the inner area of the circuit substrate but not over a semiconductor element in the outer area of the circuit substrate.

It is preferable that an oxygen content of an oxide semiconductor layer in the outer area differ from an oxygen content of an oxide semiconductor layer in the inner area.

It is preferable that an oxygen content of an oxide semiconductor layer in the outer area be greater than an oxygen content of an oxide semiconductor layer in the inner area.

It is also preferable that an oxygen content of an oxide semiconductor layer in the inner area be greater than an oxygen content of an oxide semiconductor layer in the outer area.

It is preferable that the oxide semiconductor layer be made of indium, gallium, zinc, and oxygen.

It is preferable that the semiconductor element include an etch-stop layer on a center portion of the oxide semiconductor layer.

It is preferable that the circuit substrate include a contact portion where a source electrode and the oxide semiconductor layer make contact with each other and that the contact portion overlap an outer edge of a gate electrode in a plan view of the main surface of the substrate.

It is preferable that the circuit substrate include a contact portion where a source electrode and the oxide semiconductor layer make contact with each other and that the contact portion do not overlap an outer edge of a gate electrode in a plan view of the main surface of the substrate.

It is preferable that the source electrode be a multi-layer body that is made of at least two layers including at least one layer that is selected from a group of a copper layer, a copper alloy layer, an aluminum layer and an aluminum alloy layer, and one layer that includes at least one element that is selected from a group constituted of the group 4 element to group 6 element, and that such at least one layer that is selected from a group of a copper layer, a copper alloy layer, an aluminum layer, and an aluminum alloy layer be disposed on a front side of the source electrode.

It is preferable that such at least one element that is selected from a group constituted of the group 4 element to group 6 element be at least one element that is selected from a group constituted of titanium, niobium, tantalum, molybdenum, and tungsten.

It is preferable that such at least one element that is selected from a group constituted of the group 4 element to group 6 element be titanium.

It is preferable that the semiconductor element be a thin film transistor.

It is preferable that the circuit substrate be a circuit substrate for a display device, that the inner area of the circuit substrate correspond to a display area of the display device, and that the outer area of the circuit substrate correspond to a non-display area of the display device.

One aspect of the present invention may be a display device that includes the above-mentioned circuit substrate, an opposite substrate that faces the circuit substrate, and a display element that is sandwiched by the two substrates.

### Effects of the Invention

According to the present invention, it is possible to obtain a circuit substrate and display device that are sufficiently reliable by forming the oxide semiconductor layer of a TFT such that the oxide semiconductor is optimized for each area or the like.

### BRIEF DESCRIPTION OF THE DRAWINGS

FIG. 1 is a schematic cross-sectional view showing a configuration of a TFT in an inner area of a circuit substrate of Embodiment 1.

FIG. 2 is a schematic plan view showing a configuration of a TFT in the inner area of the circuit substrate of Embodiment 1.

FIG. 3 is a schematic cross-sectional view showing a configuration of a TFT in an outer area of a circuit substrate of Embodiment 1.

FIG. 4 is a schematic diagram showing a relationship between the oxygen content and the threshold voltage shift at a bias voltage of an oxide semiconductor layer in a TFT.

FIG. 5 is a schematic cross-sectional view showing a configuration of a TFT in an inner area of a circuit substrate of Embodiment 2.

FIG. 6 is a schematic plan view showing a configuration of a TFT part in the inner area of the circuit substrate of Embodiment 2.

FIG. 7 is a schematic cross-sectional view showing a configuration of a TFT in an outer area of the circuit substrate of Embodiment 2.

FIG. 8 is a schematic cross-sectional view showing a configuration of a TFT in an inner area of a circuit substrate of Embodiment 3.

FIG. 9 is a schematic plan view showing a configuration of a TFT part in the inner area of the circuit substrate of Embodiment 3.

FIG. 10 is a schematic cross-sectional view showing a configuration of a TFT in an outer area of the circuit substrate of Embodiment 3.

FIG. 11 is a schematic cross-sectional view showing a configuration of a TFT in an inner area of a circuit substrate of Embodiment 4.

FIG. 12 is a schematic plan view showing a configuration of a TFT part in the inner area of the circuit substrate of Embodiment 4.

FIG. 13 is a schematic cross-sectional view showing a configuration of a TFT in an outer area of the circuit substrate of Embodiment 4.

FIG. 14 is a schematic cross-sectional view showing a configuration of a TFT in an inner area of a circuit substrate of Embodiment 5.

FIG. 15 is a schematic plan view showing a configuration of a TFT part in an inner area of a circuit substrate of Embodiment 5.

FIG. 16 is a schematic cross-sectional view showing a configuration of a TFT in an outer area of the circuit substrate of Embodiment 5.

FIG. 17 is a schematic cross-sectional view showing a configuration of a TFT in an inner area of a circuit substrate of Embodiment 6.

FIG. 18 is a schematic plan view showing a configuration of a TFT part in the inner area of the circuit substrate of Embodiment 6.

FIG. 19 is a schematic cross-sectional view showing a configuration of a TFT in an outer area of the circuit substrate of Embodiment 6.

FIG. 20 is a schematic plan view of a liquid crystal panel to which the circuit substrate of each embodiment above can be applied.

FIG. 21 is a wiring and terminal layout of a liquid crystal panel to which the circuit substrate of each embodiment above can be applied.

FIG. 22 is a schematic cross-sectional view of an opposite substrate in a manufacturing process thereof, the opposite substrate being included in a liquid crystal display device according to each of the embodiments above.

FIG. 23 is a schematic cross-sectional view of an opposite substrate in a manufacturing process thereof, the opposite substrate being included in a liquid crystal display device according to each of the embodiments above.

FIG. 24 is a schematic cross-sectional view of an opposite substrate in a manufacturing process thereof, the opposite substrate being included in a liquid crystal display device according to each of the embodiments above.

### DETAILED DESCRIPTION OF EMBODIMENTS

Below, embodiments of the present invention will be described to explain the present invention in further detail with reference to the figures. However, the present invention is not limited to these embodiments.

In the present specification, placing an object at a layer above a member means at least a part of the object is placed on a side of such a member that is closer to a display element.

Forming an opening in an organic insulating film on a part of an oxide semiconductor layer of a circuit substrate means, in a case of an opening on a semiconductor element, for example, if an opening is formed on a semiconductor element in an outer area of the circuit substrate, an opening is not formed in an inner area thereof, and if an opening is formed on a semiconductor element in the inner area of the circuit substrate, an opening is not formed in the outer area thereof. In the present specification, the inner area of the circuit substrate corresponds to a display area of a display device, and the outer area of the circuit substrate corresponds to a non-display area of the display device. “Corresponds to” means that the respective areas need to coincide with each other in a plan view of the main surface of the substrate.

When a negative voltage is repeatedly applied, the threshold voltage Vth of each TFT in the display area is shifted in a negative direction. This is referred to as a negative-direction Vth shift (negative shift). If a positive voltage is repeatedly applied, Vth of the TFTs is shifted in a positive direction. This is referred to as a positive-direction Vth shift (positive shift). The respective Vth shifts occur in different manners depending on the applied voltage, the current value and S/N ratio upon voltage application, and the shapes of semiconductor layer or wiring lines.

### Embodiment 1

In Embodiment 1, the oxygen content of an oxide semiconductor layer of each TFT in the GDM area is increased to suppress the negative shift since the negative shift of the characteristics of the GDM area (threshold voltage of TFTs, for example) causes display defects to occur. In a circuit substrate for a mobile display device, it is not desirable, in some cases, to drive peripheral circuits with a negative bias voltage from perspectives of reducing power consumption and the like, and the configuration of Embodiment 1 can suitably be used for such a case. Embodiment 1 describes a CE structure (channel-etch structure), and a circuit substrate includes a contact portion where a source electrode (constituted of a source metal lower layer 15s and source metal upper layer 16s) and an oxide semiconductor layer IG make contact with each other, and the contact portion does not overlap an outer edge of a gate electrode (constituted of a gate metal lower layer 12 and gate metal upper layer 13) in a plan view of the main surface of the substrate.

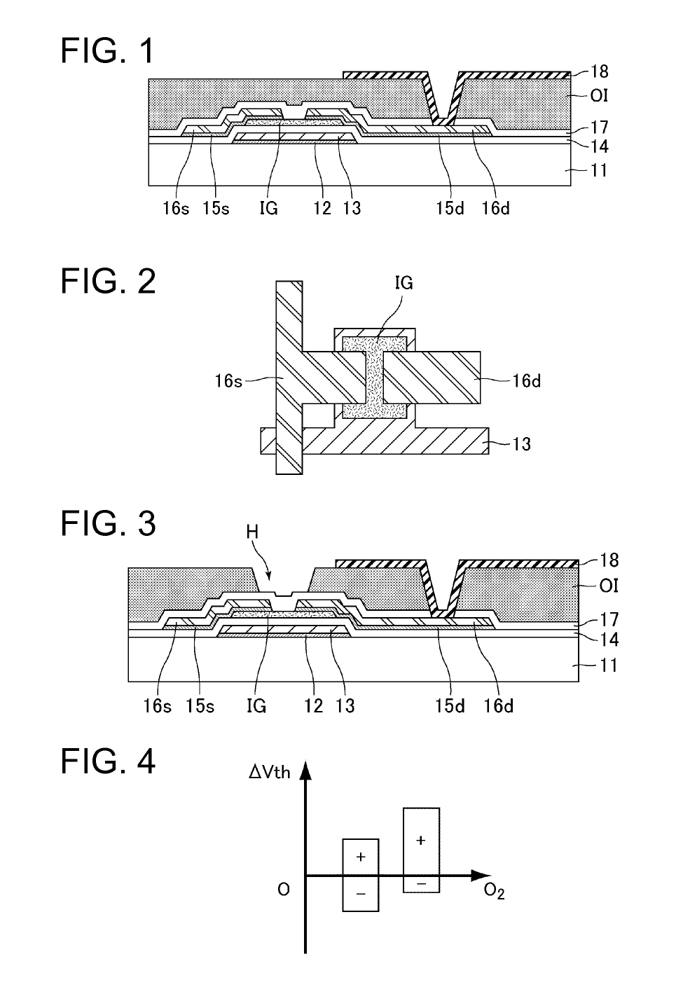

FIG. 1 is a schematic cross-sectional view showing a configuration of a TFT in an inner area of a circuit substrate of Embodiment 1. FIG. 2 is a schematic plan view showing a configuration of a TFT part in the inner area of the circuit substrate of Embodiment 1. FIG. 3 is a schematic cross-sectional view showing a configuration of a TFT in an outer area of the circuit substrate of Embodiment 1. In Embodiment 1, an organic insulating film has an opening on some TFTs but not on other TFTs. An opening is not formed in the organic insulating film on the oxide semiconductor layer in the inner area of the circuit substrate, and an opening is formed in the organic insulating film on the semiconductor elements in the outer area of the circuit substrate.

As described above, in a state in which an opening is formed in the organic insulating film on the oxide semiconductor (channel portion) of each TFT in the outer area of the circuit substrate (non-display area such as the GDM area), the following process is conducted. If oxygen is to be supplied, O₂ ashing and/or O₂ annealing is used as the method for supplying oxygen. In this manner, in the outer area of the circuit substrate where an opening is formed in the organic insulating film, oxygen is supplied to the oxide semiconductor layer of each semiconductor element (indium-gallium-zinc-oxide film, for example).

On the other hand, if oxygen is to be removed, in a circuit substrate for a display device, as opposed to the configuration shown in FIGS. 1 and 3 above, for example, an opening is formed in the organic insulating film on the oxide semiconductors (channel portions) of the TFTs in the inner area such as the display area. Thereafter, oxygen is removed from the channel portions through N₂ annealing and/or H₂ plasma. In this case, the oxide semiconductor layers are made to have excess O₂ in the entire circuit substrate in advance by conducting O₂ annealing or the like when the oxide semiconductor layers are formed. By having excess O₂, it is possible to make it harder to cause a negative shift of the threshold voltage of the semiconductor elements in the outer area of the circuit substrate, and also it is possible to appropriately adjust the oxygen concentration of the oxide semiconductors by removing oxygen from the oxide semiconductors in the display area. The oxygen removal has an effect opposite to the oxygen supply, and with the oxygen removal, the negative shift is more likely to occur (positive shift is less likely to occur) in the threshold voltage Vth of the TFTs.

With one of the above-described processes, the oxygen amount in the oxide semiconductor layer (indium-gallium-zinc-oxide film, for example) is controlled, which also controls the characteristics of TFTs and reliability of the circuit substrate. Specifically, in Embodiment 1, the oxygen content of the oxide semiconductor layers in the outer area such as the non-display area is greater than the oxygen content of the oxide semiconductor layers in the inner area such as the display area. The oxygen content of each of the outer area and inner area can be appropriately set depending on the device type (driving voltage, S/N ratio, and pattern shape) and the like.

In Embodiment 1, in the circuit substrate for a mobile display device, when it is not desirable to drive the peripheral circuits with a negative bias voltage from the perspectives of reducing power consumption and the like, the oxygen content of the oxide semiconductor layers of the semiconductor elements in the outer area of the circuit substrate (such as the non-display area) is made greater than the oxygen content of the oxide semiconductor layers of the semiconductor elements in the inner area of the circuit substrate (such as the display area). This way, a negative shift is more likely to occur in the threshold voltage Vth of the TFTs in the display area, while the negative shift of the threshold voltage Vth of the TFTs in the non-display area is sufficiently prevented.

### Modification Example of Embodiment 1

If the threshold voltage Vth of the inner area such as the display area being susceptible to the negative shift more than the outer area such as the non-display area is a problem, in order to prevent this, the oxygen content of the oxide semiconductor layers (indium-gallium-zinc-oxide film, for example) of the semiconductor elements is increased in the inner area of the circuit substrate (such as the display area) (by supplying oxygen through an opening formed in the organic insulating film on the oxide semiconductor layers in the display area, or by making the oxide semiconductor layers in the entire circuit substrate have excess O₂ in advance by conducting O₂ annealing when the oxide semiconductor layers are formed and removing oxygen from an opening formed in the organic insulating film on the oxide semiconductor layers in the non-display area, for example). This way, it is possible to make the threshold voltage Vth of the TFTs in the display area less susceptible to the negative shift. The oxygen content of each of the outer area and inner area can be appropriately set depending on the device type (driving voltage, S/N ratio, and pattern shape) and the like. The oxygen supply makes the threshold voltage Vth more susceptible to the positive shift.

FIG. 4 is a schematic diagram showing a relationship between the oxygen content and the threshold voltage shift at a bias voltage of an oxide semiconductor layer of a TFT. When the oxygen content of the oxide semiconductor layer is greater, the threshold voltage is more likely to shift toward the positive side when a positive bias voltage is applied to the circuit. On the other hand, when the oxygen content of the oxide semiconductor layer is lower, the threshold voltage is more likely to shift toward the negative side when a negative bias voltage is applied to the circuit.

In Modification Example of Embodiment 1, the oxygen content of the oxide semiconductor layers of the semiconductor elements in the inner area of the circuit substrate (display area, for example) is increased, and the oxygen content of the oxide semiconductor layers of the semiconductor elements in the outer area of the circuit substrate (non-display area, for example) is reduced. As a result, the threshold voltage Vth of the TFTs in the display area is less susceptible to the negative shift. As described above, except for the configuration for adjusting the oxygen content, the configurations of Modification Example of Embodiment 1 are similar to those described above in Embodiment 1.

The circuit substrate of Embodiment 1 and the modification example thereof is a circuit substrate in which semiconductor elements are disposed on a transparent substrate. The semiconductor element includes an oxide semiconductor layer made of an indium-gallium-zinc-oxide (In—Ga—Zn oxide) or the like. The circuit substrate includes a conductive layer constituted of source electrodes, source wiring lines, and drain electrodes. A part of the conductive layer is disposed on the semiconductor element. The conductive layer has a Cu/Ti multi-layer structure (multi-layer structure with Cu at the upper layer and Ti at the lower layer).

The implementation conditions with which the circuit substrate of Embodiment 1 was actually manufactured are described below.

### Implementation Conditions:

### (Oxygen Supply Method)

O₂ Plasma: O₂ flow was 3600 sccm; source/bias power was 25 kW/20 kW; pressure was 26 mT; and time was 60 seconds.
O₂ annealing: Conducted under O₂ atmosphere; temperature was 220° C.; and time was 60 minutes.

### (Oxygen Removal Method)

N₂ annealing: Conducted under N₂ atmosphere; temperature was 220° C.; and time was 60 minutes.
H₂ Plasma: H₂ flow was 3600 sccm; source/bias power was 25 kW/20 kW; pressure was 26 mT; and time was 60 seconds.
The source/bias power for the plasma process is set based on a G8-sized device.

Other manufacturing processes for the circuit substrate of Embodiment 1 will be explained in detail below with reference to FIGS. 1 to 3.

First, gate wiring lines (wiring lines constituted of a gate metal lower layer 12 and gate metal upper layer 13 of FIG. 1, for example) are formed on a transparent substrate 11 such as a glass substrate. In the process to form the gate wiring lines, a wiring line layer is formed, and then the wiring line layer is patterned into a desired shape by photolithography, for example. Specifically, a resist is formed through a mask process, and by etching the wiring line layer, the gate wiring lines are formed. Next, the resist is removed.

Thereafter, a gate insulating film 14 is formed. The gate insulating film 14 is a silicon nitride (SiN_{X}) film or the like, and can be formed by the PECVD (Plasma Enhanced Chemical Vapor Deposition) method or the like, for example. The gate insulating film may be made of an SiN_{X} single layer as described above, or may have a multi-layer structure of SiO₂/SiN_{X} or a single-layer structure of SiO₂.

Next, island-shaped oxide semiconductor layers IG are formed of indium-gallium-zinc-oxide or the like. The island-shaped oxide semiconductor layers can be formed by depositing the material of the oxide semiconductor layers IG to a thickness of 10 nm to 300 nm by spattering, and by patterning the formed film into a desired shape through photolithography, for example.

A conductor (source metal lower layers 15s, 15d and source metal upper layers 16s, 16d) is deposited on the oxide semiconductor layers. A resist is formed by a mask process, and by patterning the conductor S, a conductive layer constituted of source electrodes, source wiring lines, and drain electrodes is formed. Next, the resist on the substrate is removed.

It is preferable that the process to form the conductive layer include dry-etching or a combination of wet-etching and dry-etching. The oxide semiconductor is sensitive to acid, and if the conductive layer is subjected to wet-etching, the oxide semiconductor is also etched at the same time, and is possibly damaged. Therefore, the entire conductive layer, or a lower conductive layer if the conductive layer has a multi-layer structure, needs to be dry-etched.

A protective film 17 is formed. The protective film 17 is a silicon oxide (SiO₂) film or the like, and can be formed by the PECVD (Plasma Enhanced Chemical Vapor Deposition) method or the like, for example. The protective film 17 may be made of a SiO₂ single layer as described above, or may have a multi-layer structure of SiN_{X}/SiO₂ or a single-layer structure of SiN_{X}. The protective film is deposited to be 10 nm to 300 nm thick. If oxygen is to be supplied (or oxygen is to be removed) through the opening of the organic insulating film, it is preferable that the protective film 17 be made thin.

Next, an organic insulating film OI is formed. The organic insulating film OI is made of an acrylic resin, and can be formed by the slit-coating method, spin-coating method, or the like, for example. By forming the organic insulating film OI, the substrate can be planarized as shown in FIGS. 1 and 3.

Next, a pixel electrode 18 is formed on the entire surface of the organic insulating film OI. The pixel electrode 18 can be made of ITO (indium tin oxide), but may also be formed of another type of transparent electrode such as IZO (indium zinc oxide) instead of ITO.

The members and the like described in the manufacturing process of the circuit substrate of Embodiment 1 above will be explained in detail below.

The conductive layer is constituted of a source metal. The source metal refers to the source wiring lines and members that are formed in the same process as the source wiring lines (such as source electrodes and drain electrodes).

The conductive layer described above is constituted of multiple layers of Cu/Ti, but instead of this configuration, a layer that includes an aluminum layer, aluminum alloy layer, copper layer, and copper alloy layer can suitably be used.

The aluminum layer is a layer that is substantially made of an aluminum metal only. In manufacturing the wiring lines that include an aluminum layer, it is possible that elements are diffused from other metal materials, interlayer insulating film, and the like that make contact with the aluminum layer, and therefore, in some cases, the aluminum layer includes a very small amount of impurity elements. The aluminum alloy layer needs to include aluminum, and may also include other metal elements or non-metal elements such as silicon. Examples of the metal elements that are included in the aluminum alloy include nickel, iron, and cobalt. It is more preferable to add boron, neodymium, or lanthanum as an additional element to the aluminum alloy.

The copper layer is a layer that is substantially made of copper only. Because it is possible that elements are diffused from other metal materials, interlayer insulating film, and the like that make contact with the copper layer, the copper layer includes a very small amount of impurity elements in some cases. The copper alloy layer needs to include copper, and may also include other metal elements or non-metal elements such as carbon or silicon. Examples of metal elements that are added to the copper alloy include magnesium and manganese.

Other metal elements may appropriately be used for the conductive layer.

The wiring lines are signal wiring lines for transmitting electric signals, power wiring lines for supplying power, wiring lines that constitute a circuit, wiring lines for applying electric field (applying electric field to the gate of a TFT, for example) and the like. When the circuit substrate of the present invention is applied to a liquid crystal display device, the circuit substrate of the present invention may also include auxiliary capacitance wiring lines that form auxiliary capacitances for holding voltages that were applied to the liquid crystal.

It is preferable that the semiconductor element be a thin film transistor (TFT). When the TFT is used for an active matrix substrate for a display device, for example, the source wiring line is electrically connected to a pixel electrode of a display pixel through the source electrode and the drain electrode of the TFT.

There is no special limitation on the transparent substrate, and various types of substrate can be used. A single crystal semiconductor substrate, oxide single crystal substrate, metal substrate, glass substrate, quartz substrate, resin substrate, and the like may be used, for example. If a conductive substrate such as a single crystal semiconductor substrate or metal substrate is used, for example, it is preferable to form an insulating film or the like thereon.

The above-mentioned gate insulating film, protective film, organic insulating film, and the like may be constituted of a single layer or two layers or more.

It is preferable that the pixel electrode be a transparent conductive film. Generally, the transparent conductive film is made of indium tin oxide, indium zinc oxide, or the like, and can therefore be used for the circuit substrate of the present invention.

### Embodiment 2

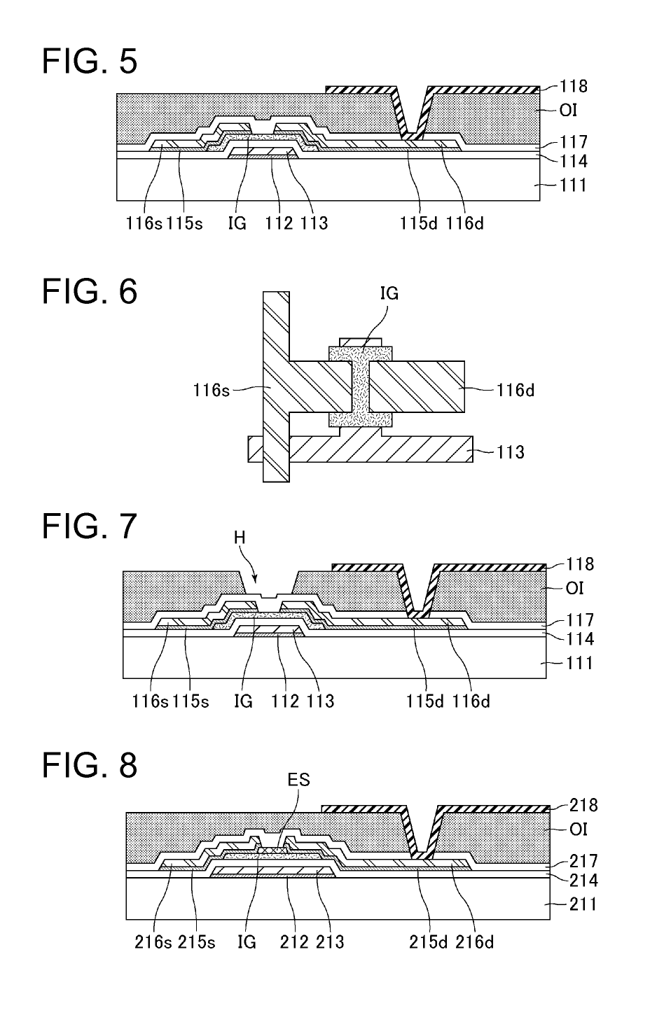

FIG. 5 is a schematic cross-sectional view showing a configuration of a TFT in an inner area of a circuit substrate of Embodiment 2. FIG. 6 is a schematic plan view showing a configuration of a TFT part in the inner area of the circuit substrate of Embodiment 2. FIG. 7 is a schematic cross-sectional view showing a configuration of a TFT in an outer area of the circuit substrate of Embodiment 2. In a manner similar to Embodiment 1, Embodiment 2 describes the CE structure (channel-etch structure). A circuit substrate of Embodiment 2 includes a contact portion where a source electrode (constituted of a source metal lower layer 115s and source metal upper layer 116s) makes contact with an oxide semiconductor layer IG, and the contact portion overlaps an outer edge of a gate electrode (constituted of a gate metal lower layer 112 and gate metal upper layer 113) in a plan view of the main surface of the substrate. Other configurations are similar to those of Embodiment 1.

### Modification Example of Embodiment 2

The configuration of Modification Example of Embodiment 2 is similar to the configuration of Embodiment 2 except that the oxygen content of the oxide semiconductor layer of the semiconductor element in the display area of the circuit substrate is greater than that in the non-display area of the circuit substrate.

### Embodiment 3

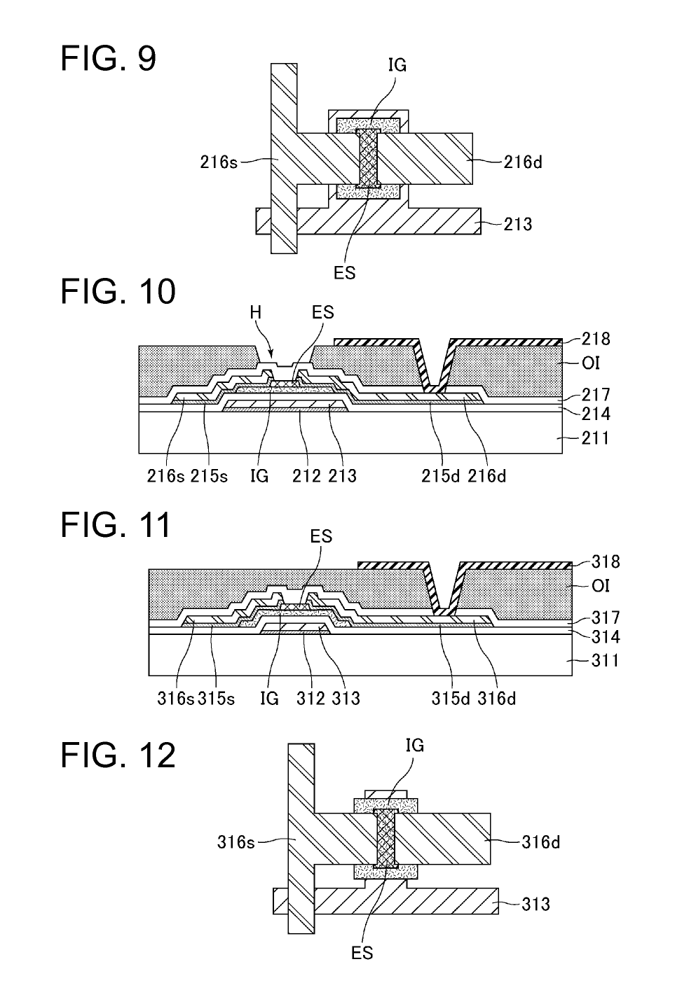

FIG. 8 is a schematic cross-sectional view showing a configuration of a TFT in an inner area of a circuit substrate of Embodiment 3. FIG. 9 is a schematic plan view showing a configuration of a TFT part in the inner area of the circuit substrate of Embodiment 3. FIG. 10 is a schematic cross-sectional view showing a configuration of a TFT in an outer area of the circuit substrate of Embodiment 3.

Embodiment 3 shows a structure in which an etch-stop layer is provided (also referred to as an ES structure), and the etch-stop layer ES is disposed only on the channel portion of the oxide semiconductor layer. The circuit substrate of Embodiment 3 includes a contact portion where a source electrode (constituted of a source metal lower layer 215s and source metal upper layer 216s) and an oxide semiconductor layer IG make contact with each other, and the contact portion does not overlap an outer edge of a gate electrode (constituted of a gate metal lower layer 212 and gate metal upper layer 213) in a plan view of the main surface of the substrate.

In the circuit substrate according to Embodiment 3, an etch-stop layer ES made of an insulating material is disposed so as to cover the center portion (channel portion) of the oxide semiconductor layer. The circuit substrate includes a conductive layer (constituted of the source metal lower layers 215s, 215d and source metal upper layers 216s, 216d) that is constituted of source electrodes, source wiring lines, and drain electrodes. At least a part of the conductive layer is disposed on each of the etch-stop layers ES.

A manufacturing process for the circuit substrate of Embodiment 3 is similar to that of Embodiment 1 except that a step to form an etch-stop layer ES is included between the oxide semiconductor layer forming process and the conductive layer forming process.

After forming the oxide semiconductor layer IG, an etch-stop layer ES is formed. The etch-stop layer ES is formed, for example, by forming an insulating film having a thickness of 10 nm to 300 nm using an insulating material containing silicon (such as silicon oxide film (SiO₂), silicon nitride film (SiN_{X}), or silicon nitride oxide film (SiNO)) by the plasma CVD (chemical vapor deposition) method or sputtering, and by thereafter etching the insulating film using a resist formed by a mask process. The etch-stop layer ES is formed so as to cover the center portion of the island-shaped oxide semiconductor layer IG. Next, the resist is removed. The etch-stop layer ES is added in this manner in order to improve the reliability of the circuit substrate that has the oxide semiconductor layer IG formed therein.

Next, in a manner similar to Embodiment 1, the conductive layer (made of the source metal lower layers 215s, 215d and the source metal upper layers 216s, 216d) is formed.

The above-mentioned etch-stop layer may be constituted of a single layer or two layers or more.

The configuration of Embodiment 3 is similar to the configuration of Embodiment 1 except that the etch-stop layer is formed as described above.

### Modification Example of Embodiment 3

The configuration of Modification Example of Embodiment 3 is similar to the configuration of Embodiment 3 except that the oxygen content of the oxide semiconductor layer of the semiconductor element in the display area of the circuit substrate is greater than that in the non-display area of the circuit substrate.

### Embodiment 4

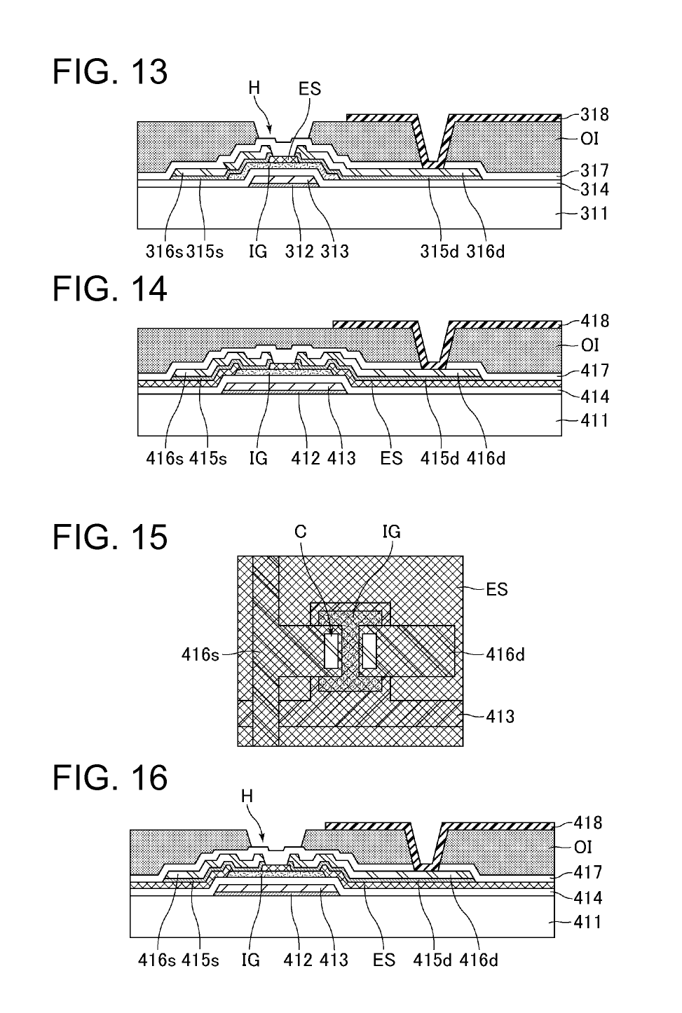

FIG. 11 is a schematic cross-sectional view showing a configuration of a TFT in an inner area of a circuit substrate of Embodiment 4. FIG. 12 is a schematic plan view showing a configuration of a TFT part in the inner area of the circuit substrate of Embodiment 4. FIG. 13 is a schematic cross-sectional view showing a configuration of a TFT in an outer area of the circuit substrate of Embodiment 4. A circuit substrate of Embodiment 4 includes a contact portion where a source electrode (constituted of a source metal lower layer 315s and source metal upper layer 316s) and an oxide semiconductor layer make contact with each other, and the contact portion overlaps an outer edge of a gate electrode (constituted of a gate metal lower layer 312 and gate metal upper layer 313) in a plan view of the main surface of the substrate. Other configurations are similar to those of Embodiment 3.

### Modification Example of Embodiment 4

The configuration of Modification Example of Embodiment 4 is similar to the configuration of Embodiment 4 except that the oxygen content of the oxide semiconductor layer of the semiconductor element in the display area of the circuit substrate is greater than that in the non-display area of the circuit substrate.

### Embodiment 5

FIG. 14 is a schematic cross-sectional view showing a configuration of a TFT in an inner area of a circuit substrate of Embodiment 5. FIG. 15 is a schematic plan view showing a configuration of a TFT part in the inner area of the circuit substrate of Embodiment 5. FIG. 16 is a schematic cross-sectional view showing a configuration of a TFT in an outer area of the circuit substrate of Embodiment 5. Embodiment 5 shows a structure in which an etch-stop layer is provided (also referred to as ES structure), and the etch-stop layer ES is disposed in an area other than contact portions where a source electrode makes contact with an oxide semiconductor layer in a plan view of the main surface of the substrate. Other configurations are similar to those of Embodiment 1.

### Modification Example of Embodiment 5

The configuration of Modification Example of Embodiment 5 is similar to the configuration of Embodiment 5 except that the oxygen content of the oxide semiconductor layer of the semiconductor element in the display area of the circuit substrate is greater than that in the non-display area of the circuit substrate.

### Embodiment 6

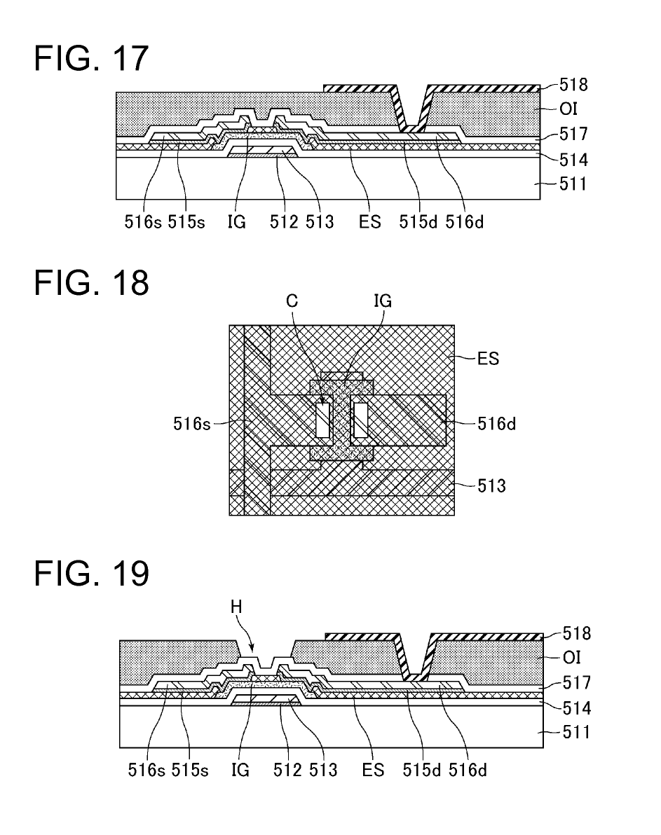

FIG. 17 is a schematic cross-sectional view showing a configuration of a TFT in an inner area of a circuit substrate of Embodiment 6. FIG. 18 is a schematic plan view showing a configuration of a TFT part in the inner area of the circuit substrate of Embodiment 6. FIG. 19 is a schematic cross-sectional view showing a configuration of a TFT in an outer area of the circuit substrate of Embodiment 6. A circuit substrate of Embodiment 6 includes contact portions where a source electrode makes contact with an oxide semiconductor layer, and the contact portions overlap respective outer edges of a gate electrode in a plan view of the main surface of the substrate. Other configurations are similar to those of Embodiment 5.

### Modification Example of Embodiment 6

The configuration of Modification Example of Embodiment 6 is similar to the configuration of Embodiment 6 except that the oxygen content of the oxide semiconductor layer of the semiconductor element in the display area of the circuit substrate is greater than that in the non-display area of the circuit substrate.

The present invention can suitably be applied to either one of the ES structure and CE structure and either one of the overlapping structure and the non-overlapping structure described above.

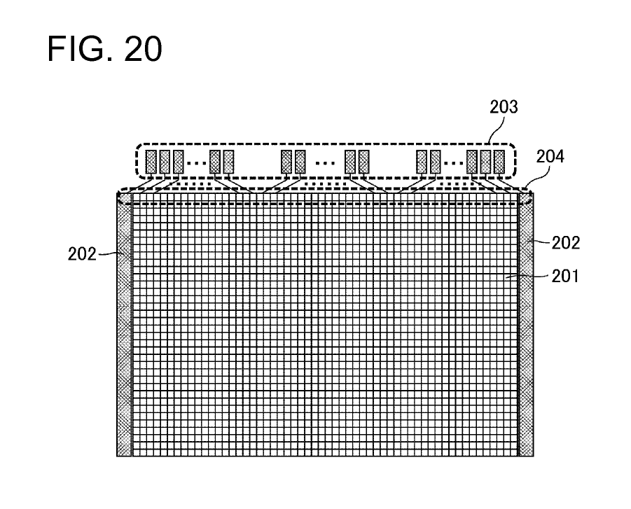

FIG. 20 is a schematic plan view of a liquid crystal panel to which the circuit substrate of each of the embodiments above can be applied. A display area (area in which pixel electrodes are disposed) 201 and a peripheral circuit area (GDM area) 202 are connected electrically to a connecting terminal part 203 through a wiring line connecting part 204.

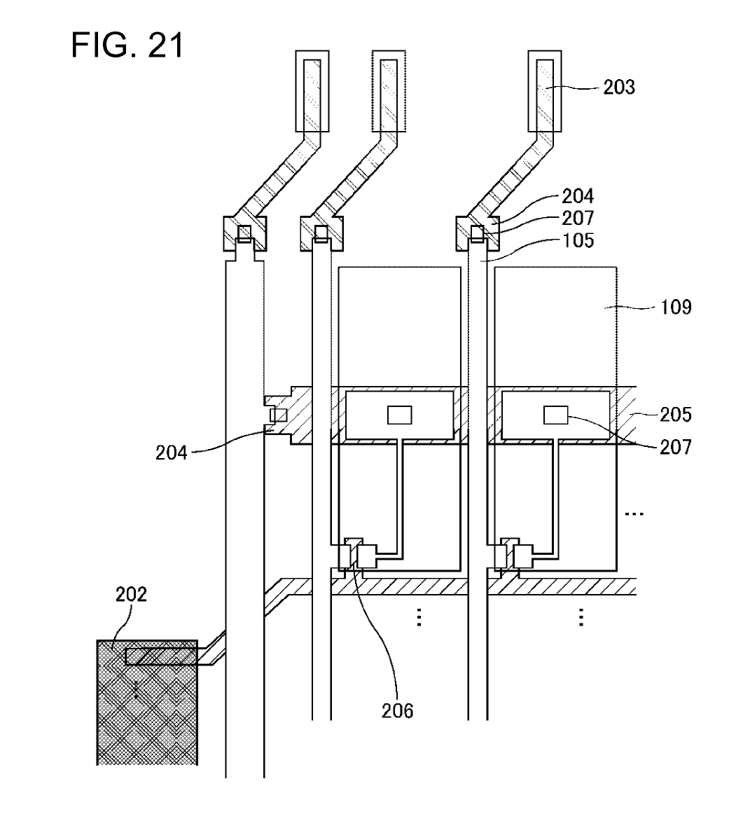

FIG. 21 is a wiring and terminal layout of a liquid crystal panel to which the circuit substrate of each of the embodiments above can be applied. The connecting terminal part 203 is electrically connected to a source bus line 105 through an opening 207 of the interlayer insulating film (opening in the non-display area) in the wiring line connecting part 204. An auxiliary capacitance wiring line 205 is connected to a wiring line in the wiring line connecting part 204. The source bus line 105 is connected to the drain electrode through a TFT element part 206, and the drain electrode is electrically connected to a pixel electrode 109 through the opening 207 of the interlayer insulating film, which corresponds in position to the center portion of the pixel electrode 109. A gate bus line that extends from the TFT element part 206 is electrically connected to the peripheral circuit area (GDM area) 202. A GDM area having a typical configuration in the technical field of the present invention can appropriately be used for the GDM area of the present invention.

The circuit substrate of each of the embodiments above is bonded to an opposite substrate, and by injecting liquid crystal therein, a liquid crystal display panel is manufactured. By adding a polarizing plate and other members to this liquid crystal display panel, a liquid crystal display device is obtained.

Method for Manufacturing Opposite Substrate (Color Filter Substrate)

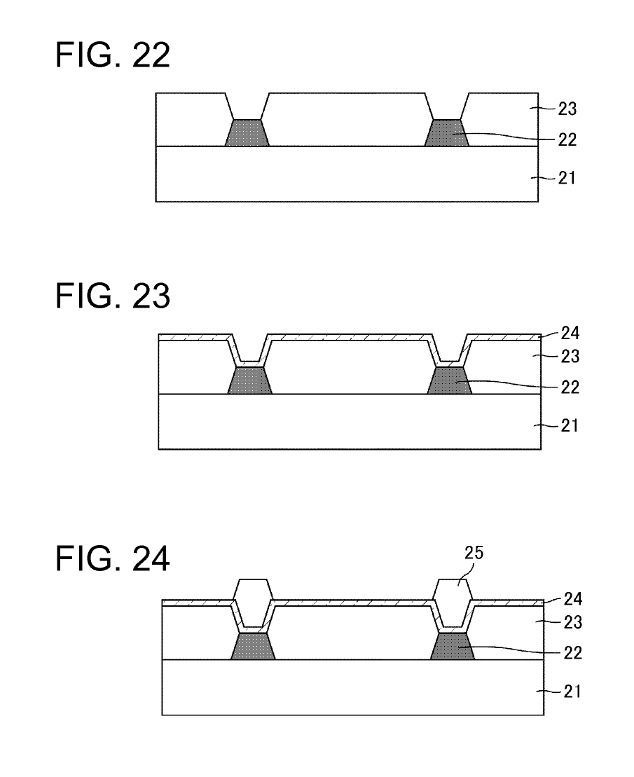

FIGS. 22 to 24 are schematic cross-sectional views each showing a manufacturing process (manufacturing processes (1) to (3)) of an opposite substrate provided in the liquid crystal display device of each of the embodiments above.

### (1) Forming Back Matrix and Color Filters (FIG. 22)

In each of the embodiments above, a black matrix and color filter layers of red, green, blue, or the like are formed by photolithography using a photosensitive material.

### (2) Forming Opposite Electrode (FIG. 23)

In each of the embodiments above, after depositing an ITO film to a thickness of 50 to 200 nm by sputtering, the ITO film is patterned through photolithography and wet-etching, thereby forming an opposite electrode.

### (3) Forming Photo-Spacers (FIG. 24)

In each of the embodiments above, photo-spacers 25 are formed by photolithography using a photosensitive material.

Below, processes for manufacturing a liquid crystal display device (processes (1) to (3)) will be explained.

Bonding and Liquid Crystal Process

### (1) Forming Alignment Films

Alignment films are formed by a printing method using polyimide on an active matrix substrate and an opposite substrate that are manufactured through the processes described above, respectively.

### (2) Liquid Crystal Dropping and Bonding

After printing a sealing agent and dropping liquid crystal on the active matrix substrate and the opposite substrate that are manufactured through the processes described above, respectively, the two substrates are bonded to each other.

### (3) Glass Cutting

The bonded substrates are cut by dicing.

### Other Embodiments

The conductive layer in the embodiments above mainly had a Cu/Ti multi-layer structure, but the metal constituting the lower layer may be different from Ti. The metal that constitutes the lower layer may be Mo, MoN, TiN, W, Nb, Ta, MoTi, or MoW, for example.

The oxide semiconductor in the embodiments above was mainly made of indium-gallium-zinc-oxide, but another type of oxide semiconductor may also be used. Examples of an oxide semiconductor that can be used includes an oxide semiconductor made of In, Si, Zn and O, an oxide semiconductor made of Sn, Si, Zn, and O, an oxide semiconductor made of Sn, Al, Zn, and O, an oxide semiconductor made of Sn, Ga, Zn, and O, an oxide semiconductor made of Ga, Si, Zn, and O, an oxide semiconductor made of Ga, Al, Zn, and O, an oxide semiconductor made of In, Cu, Zn, and O, an oxide semiconductor made of Sn, Cu, Zn, and O, an oxide semiconductor made of Zn and O, and an oxide a semiconductor made of In and O. In addition to those, various types of known oxide semiconductor may be used.

It is preferable that the circuit substrate be a circuit substrate for a display device as describe above, but the present invention may also be appropriately used for other purposes.

It is preferable that the display device be a liquid crystal display device, but as long as the display device includes a circuit substrate, an opposite substrate that faces the circuit substrate, and a display element that is sandwiched between the two substrates, other types of display device may also be used (such as an organic electroluminescence display device, inorganic electroluminescence display device, and a display device using electrophoresis).

The circuit substrate of each of the embodiments above can be disassembled, and the shape and the like of the circuit substrate can be confirmed through an observation using a microscope such as an optical microscope, STEM (scanning transmission electron microscope), and SEM (scanning electron microscope).

The materials and the like of the members that are used for the circuit substrate can be confirmed through a material analysis method that is generally used.

The respective configurations of the embodiments described above may be appropriately combined without departing from the scope of the present invention.

### DESCRIPTION OF REFERENCE CHARACTERS

11, 111, 211, 311, 411, 511 Transparent Substrate
12, 112, 212, 312, 412, 512 Gate metal lower layer
13, 113, 213, 313, 413, 513 Gate metal upper layer
14, 114, 214, 314, 414, 514 Gate insulating film
15s, 115s, 215s, 315s, 415s, 515s Source metal lower layer
16s, 116s, 216s, 316s, 416s, 516s Source metal upper layer
15d, 115d, 215d, 315d, 415d, 515d Source metal (drain electrode) lower layer
16d, 116d, 216d, 316d, 416d, 516d Source metal (drain electrode) upper layer
17, 117, 217, 317, 417, 517 Protective film
18, 118, 218, 318, 418, 518 Pixel electrode
Glass
Black matrix
Color filter
Opposite electrode
Photo-spacer
105 Source bus line
109 Pixel electrode
201 Display area (pixel electrode arrangement area)
202 Peripheral circuit area (GDM area)
203 Connecting terminal part
204 Wiring line connecting part
205 Auxiliary capacitance wiring line
206 TFT element part
207 Opening of interlayer insulating film
C Contact hole
ES Etch-stop layer
H Opening
IG Oxide semiconductor layer
OI Organic insulating film

1. A circuit substrate, comprising:
a transparent substrate;
semiconductor elements disposed on the transparent substrate, each of the semiconductor elements including an oxide semiconductor layer;
a protective film over the semiconductor elements; and
an organic insulating film over the protective film,
wherein the organic insulating film has an opening in a position corresponding to at least a part of the oxide semiconductor layer.

2. The circuit substrate according to claim 1, wherein the opening is formed over a semiconductor element in an outer area of the circuit substrate but not over a semiconductor element in an inner area of the circuit substrate, or the opening is formed over a semiconductor element in the inner area of the circuit substrate but not over a semiconductor element in the outer area of the circuit substrate.

3. The circuit substrate according to claim 1, wherein an oxygen content of an oxide semiconductor layer in the outer area differs from an oxygen content of an oxide semiconductor layer in the inner area.

4. The circuit substrate according to claim 3, wherein an oxygen content of an oxide semiconductor layer in the outer area is greater than an oxygen content of an oxide semiconductor layer in the inner area.

5. The circuit substrate according to claim 3, wherein an oxygen content of an oxide semiconductor layer in the inner area is greater than an oxygen content of an oxide semiconductor layer in the outer area.

6. The circuit substrate according to claim 1, wherein the oxide semiconductor layer is made of indium, gallium, zinc, and oxygen.

7. The circuit substrate according to claim 1, wherein the semiconductor element includes an etch-stop layer on a center portion of the oxide semiconductor layer.

8. The circuit substrate according to claim 1, wherein the circuit substrate has a contact portion where a source electrode and an oxide semiconductor layer make contact with each other, and the contact portion overlaps an outer edge of a gate electrode in a plan view of a main surface of the substrate.

9. The circuit substrate according to claim 1, wherein the circuit substrate has a contact portion where a source electrode and an oxide semiconductor layer make contact with each other, and the contact portion does not overlap an outer edge of a gate electrode in a plan view of the main surface of the substrate.

10. The circuit substrate according to claim 1,
wherein the source electrode is a multi-layer body that is made of at least two layers including at least one layer that is selected from a group of a copper layer, a copper alloy layer, an aluminum layer, and an aluminum alloy layer, and one layer that includes at least one element that is selected from a group made of a group 4 element to group 6 element, and
wherein said at least one layer that is selected from a group of a copper layer, a copper alloy layer, an aluminum layer, and an aluminum alloy layer is disposed on a front side of the source electrode.

11. The circuit substrate according to claim 10, wherein said at least one element that is selected from a group made of the group 4 element to group 6 element is at least one element that is selected from a group made of titanium, niobium, tantalum, molybdenum, and tungsten.

12. The circuit substrate according to claim 1, wherein the semiconductor element is a thin film transistor.

13. The circuit substrate according to claim 2,
wherein the circuit substrate is a circuit substrate for a display device,
wherein the inner area of the circuit substrate is a display area of a display device, and
wherein the outer area of the circuit substrate is a non-display area of the display device.

14. A display device, comprising:
the circuit substrate according to claim 1;
an opposite substrate that faces the circuit substrate; and
a display element sandwiched by the two substrates.

15. The circuit substrate according to claim 3,
wherein the circuit substrate is a circuit substrate for a display device,
wherein the inner area of the circuit substrate is a display area of a display device, and
wherein the outer area of the circuit substrate is a non-display area of the display device.
